(19) United States
(12) Patent Application Publication
(10) Pub. No.: US 2008/0169471 A1
(43) Pub. Date: Jul. 17, 2008

(54) Display substrate and method of manufacturing the same

(75) Inventors: Won-Suk Shin, Yongin-si (KR); Hong-Sick Park, Suwon-si (KR); Jong-Hyun Choung, Suwon-si (KR); Sun-Young Hong, Yongin-si (KR); Bong-Kyun Kim, Nam-gu (KR); Byeong-Jin Lee, Yongin-si (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 12/008,156

(22) Filed: Jan. 8, 2008

(30) Foreign Application Priority Data
Jan. 12, 2007 (KR) 10-2007-0003969

(51) Int. Cl. H01L 29/04; H01L 21/84

(52) U.S. Cl. 257/59; 438/155; 257/E29.003; 257/E21.7

(57) ABSTRACT

A display substrate includes a gate line, a data line, a pixel electrode and a source pad part. The gate line is formed on a base substrate. The data line crosses the gate line to define a pixel area. The pixel electrode makes contact with the base substrate. The source pad part is formed on an end portion of the data line, the source pad part including a source metal layer, a conductive etch stop layer formed on the source metal layer and a source pad electrode formed on the conductive etch stop layer. Thus, the conductive etch stop layer of the source pad part prevents the source metal layer of the source pad part from being damaged and the conductive etch stop layer of the source pad part may fully make contact with the source pad electrode.

### CROSS-REFERENCE TO RELATED APPLICATIONS

This application claims priority under 35 U.S.C. § 119 to Korean Patent Application No. 10-2007-0003969 filed on Jan. 12, 2007 in the Korean Intellectual Property Office (KIPO), the contents of which are herein incorporated by reference in their entirety.

### BACKGROUND OF THE INVENTION

1. Field of the Invention

The present invention relates to a display substrate and a method of manufacturing the display substrate. More particularly, the present invention relates to a display substrate for enhancing reliability in a product and a manufacturing process thereof and a method of manufacturing the display substrate.

2. Description of the Related Art

In general, a mask is required for manufacturing a display substrate, and decreasing a frequency of required masking process when manufacturing the display substrate is required to reduce a manufacturing time and costs. For example, a five-mask process is a manufacturing process in which five masks are used in five different processes such as a gate metal patterning process, a channel patterning process, a source metal patterning process, a passivation layer patterning process and a pixel electrode patterning process. A four-mask process is a manufacturing process in which a channel patterning process and a source metal patterning process are performed using a mask from the five-mask process.

A three-mask process, i.e., a manufacturing process in which a passivation layer patterning process and a pixel electrode patterning process are performed by a mask from the four-mask process, has been developed.

A contact hole for the gate pad portion and a contact hole for a source pad portion are formed by a process forming a contact portion to connect between the switching element and the pixel electrode. A passivation layer formed on a source metal layer of the source pad portion is removed to form a contact hole for the source pad portion. A gate insulation layer and a passivation layer formed on a gate metal layer of the gate pad portion are removed to form a contact hole of the gate pad portion during the formation process of the contact hole in the source pad portion. Therefore, the source metal layer for the source pad portion is damaged while performing the removal process and formation process.

More, particularly, in the three-mask process using a lift-off of the photoresist pattern, a patterning process of the photoresist film and an under-cut formation process between the photoresist pattern and the passivation layer are performed, so that a damaged amount of the source metal layer according to the three-mask process is greater than that of the source metal layer according to the four-mask or the five-mask process. The damage to the source metal layer of the source pad portion deteriorates electric characteristics of the display substrate. Therefore, in order to solve the problem above, a condition in a manufacturing process needs to be readjusted or a stepped portion between the gate pad portion and the source pad portion needs to be removed. However, the damage to the source metal layer may not be minimized.

### SUMMARY OF THE INVENTION

The present invention provides a display substrate which decreases damage to a source pad part.

The present invention also provides a method of manufacturing a display substrate for enhancing reliability of a manufacturing process.

In one aspect of the present invention, a display substrate includes a gate line, a data line, a pixel electrode and a source pad part. The gate line is formed on a base substrate. The data line crosses the gate line. The pixel electrode makes contact with the base substrate. The pixel electrode is positioned in a pixel area. The source pad part is formed on an end portion of the data line, the source pad part comprising a source metal layer, a conductive etch stop layer formed on the source metal layer and a source pad electrode formed on the conductive etch stop layer.

In another aspect of the present invention, a gate metal layer is formed on a base substrate. A gate line and a storage electrode are formed by patterning the gate metal layer. A gate insulation layer is formed on the gate line and the storage electrode. A source metal layer and a conductive etch stop layer are formed on the gate insulation layer. A data line and a source end pattern are formed on an end portion of the data line by patterning the source metal layer and the conductive etch stop layer. A pixel electrode and a source pad electrode are formed. The pixel electrode makes contact with the base substrate of a pixel area. The source pad electrode makes contact with the conductive etch stop layer of the source end pattern.

According to the display substrate and the method of manufacturing the display substrate, the conductive etch stop layer of the source pad part prevents from damaging the source metal layer of the source pad part, and the conductive etch stop layer of the source pad part may fully make contact with the source pad electrode. Therefore, contact reliability of the source pad part and reliability of the manufacturing process may be enhanced.

### BRIEF DESCRIPTION OF THE DRAWINGS

The above and other advantages of the present invention will become readily apparent by reference to the following detailed description when considered in conjunction with the accompanying drawings wherein:

FIG. 1 is a plan view illustrating a display substrate according to an embodiment of the present invention;

FIG. 2 is a cross-sectional view of the display substrate of FIG. 1 taken along a line I-I′ in FIG. 1; and

FIGS. 3 to 8 are cross-sectional views illustrating a method of manufacturing the display substrate in FIGS. 1 and 2.

### DESCRIPTION OF THE EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms such as first, second, and third may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be described in detail with reference to the accompanying drawings.

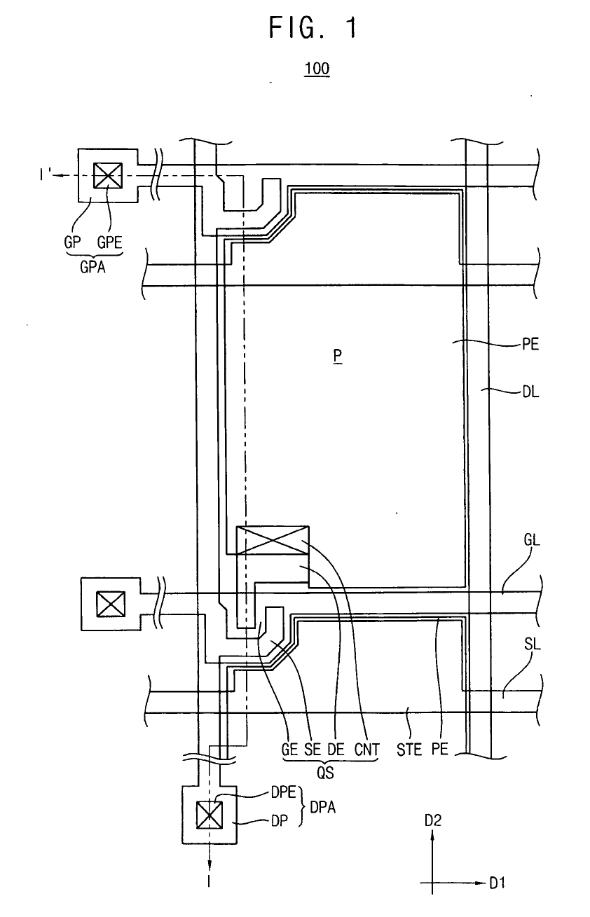

FIG. 1 is a plan view illustrating a display substrate according to an example embodiment of the present invention.

Referring to FIG. 1, a display substrate 100 includes a gate line GL, a data line DL, a thin-film transistor (TFT) QS, a pixel electrode PE and a storage line SL. In one exemplary embodiment, the gate line GL and the data line DL define a pixel area P, however the pixel area P may also be otherwise defined. The TFT QS is formed in the pixel area P. A gate pad part GPA is formed at an end portion of the gate line GL, and a source pad part DPA is formed in an end portion of the data line DL.

The gate line GL extends along a first direction D1 of the display substrate 100. A plurality of the gate lines GLs is arranged in a second direction D2 perpendicular to the first direction D1. The data line DL extends along the second direction D2 of the display substrate 100. A plurality of the data lines DLs is arranged in the first direction D1.

The TFT QS is electrically connected to the gate line GL and the data line DL. The TFT QS includes a gate electrode GE, a source electrode SE and a drain electrode DE. The gate electrode GE is electrically connected to the gate line GL, and the source electrode SE is electrically connected to the data line DL. The drain electrode DE is spaced apart from the source electrode SE. A contact portion CNT of the TFT QS, i.e., an end portion of the drain electrode DE, is connected to the pixel electrode PE so that the TFT QS and the pixel electrode PE are electrically connected to each other.

The gate pad part GPA and the source pad part DPA are formed in a peripheral area of the pixel area P to receive a gate drive signal and a data drive signal from an external device. The gate pad part GPA includes a gate end pattern GP which extends from the gate line GL to be connected to the gate line GL, and a gate pad electrode GPE formed on the gate end pattern GP. The source pad part DPA includes a source end pattern DP extended from the data line DL to be connected to the data line DL, and a source pad electrode DPE formed on the source end pattern DP.

The storage line SL extends along the first direction D1 in parallel with the gate line GL. The storage line SL is connected to a storage electrode STE formed in the pixel area P. The storage line SL is connected to the storage electrodes STE that are formed adjacent to each other. A width of the storage electrode STE may be greater than that of the storage line SL.

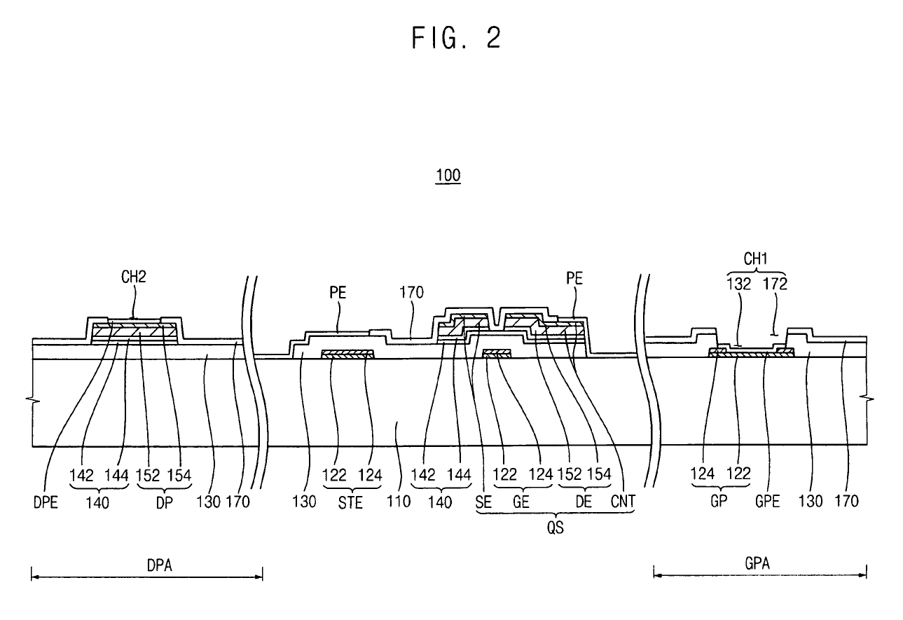

FIG. 2 is a cross-sectional view of the display substrate of FIG. 1 taken along a line I-I′ in FIG. 1.

Referring to FIGS. 1 and 2, the display substrate 100 includes gate patterns GE, GP and STE, source patterns SE, CNT and DP, and transparent electrode patterns PE, GPE and DPE. The gate patterns GE, GP and STE are formed by the same material in the gate metal layers 122 and 124 formed on a base substrate 110. The source patterns SE, CNT and DP are formed by a sequentially formed structure of a source metal layer 152. Here, the sequentially formed structure of the source metal layer 152 is formed by the same material in the data line DL and a conductive etch stop layer 154. The transparent electrode patterns PE, GPE and DPE are formed by a transparent conductive layer.

The display substrate 100 may further include a gate insulation layer 130 formed on the base substrate 110 having the gate patterns GE, GP and STE, a semiconductor pattern 140 formed on the gate insulation layer 130, and a passivation layer 170 formed on the base substrate 110 having the source patterns SE, GE, CNT and DP.

For example, the gate patterns GE, GP and STE include the gate electrode GE, the gate end pattern GP and the storage electrode STE. The gate patterns GE, GP and STE may further include the gate line GL and the storage line SL. The gate patterns GE, GP and STE are formed by patterning the gate metal layers 122 and 124 formed on the base substrate 110. The gate metal layers 122 and 124 may include a single-layered structure or a double-layered structure. In one example, when the gate metal layers 122 and 124 include the single-layered structure, the gate metal layers 122 and 124 are formed by aluminum (Al) or aluminum-neodinum (Al—Nd) alloy. In another example, when the gate metal layers 122 and 124 include the double-layered structure having different mechanical and chemical characteristics. Examples of a conductive material that can be used for a first metal layer 122 of the gate metal layers 122 and 124 include chrome (Cr), molybdenum (Mo), and molybdenum alloy. A second metal layer 124 of the gate metal layers 122 and 124 is formed by a material having relatively low specific resistance such as aluminum (Al) and aluminum alloy. The first metal layer 122 corresponds to a main metal layer providing the gate drive signal. The second metal layer 124 may protect the first metal layer 122 from being damaged in a manufacturing process of the display substrate 100. Although the above-described example embodiment discusses only a single-layered structure and a double-layered structure, a multi-layered structure such as a triple-layered structure, a four-layered structure or any other configuration known to those skilled in the art may also be utilized in place of or in conjunction with the single-layered structure or the double-layered structure.

The gate insulation layer 130 is formed on the base substrate 110 having the gate patterns GE, GP and STE. The gate insulation layer 130 may include, for example, silicon nitride (SiNx). A first hole 132 of a first contact hole CH1 is formed in the gate insulation layer 130 to expose the gate end pattern GP. For example, an end portion of the second metal layer 124 of the gate end pattern GP and a surface of the first metal layer 122 may be exposed through the first hole 132. The surface of the first metal layer 122 may be exposed through a hole in the second metal layer 124 that forms an end portion of the second metal layer 124.

The source patterns SE and DP include the source electrode SE, the drain electrode DE and the source end pattern DP. The source patterns SE, GE, CNT and DP may further include the data line DL. The source patterns SE, GE, CNT and DP are formed by patterning the source metal layer 152 that is formed on the gate insulation layer 130 and the conductive etch stop layer 154 that is formed on the source metal layer 152. The source metal layer 152 may include, for example, molybdenum (Mo). The conductive etch stop layer 154 has conductive characteristics, and makes contact with the source metal layer 152 to be electrically connected to the source metal layer 152. The source etch stop layer 154 may include indium zinc oxide (IZO). The conductive etch stop layer 154 is formed on the source metal layer 152, so that the source metal layer 152 may be prevented from being damaged.

The semiconductor pattern 140 is formed on the gate insulation layer 130, and formed below the source patterns SE, DE, CNT and DP in correspondence with the source patterns SE, DE, CNT and DP. The semiconductor pattern 140 is formed between the gate insulation layer 130 and the source metal layer 152 of the source patterns SE, DE, CNT and DP. The semiconductor pattern 140 includes a semiconductor layer 142 and the ohmic contact layer 144 that are sequentially formed on the gate insulation layer 130. The semiconductor layer 142 may include amorphous silicon. The ohmic contact layer 144 may include N+ amorphous silicon that is formed by implanting N+ impurities at a high concentration. For example, phosphorous (P) may be implanted into an upper portion of the semiconductor layer 223 to form the ohmic contact layer 144. The ohmic contact layer 144 is partially removed so that the semiconductor layer 142 is partially exposed.

The passivation layer 170 is formed on the base substrate 110 including the source patterns SE, DE, CNT and DP. The passivation layer 170 may include, for example, silicon nitride (SiNx). A second contact hole CH2 is formed in the passivation layer 170, which exposes the source end pattern DP. The conductive etch stop layer 154 of the source end pattern DP is exposed through the second contact hole CH2. The conductive etch stop layer 154 of the source end pattern DP may minimize damage to the source metal layer 152 of the source end pattern DP in a process forming the second contact hole CH2 of the passivation layer 170. The second contact hole CH2 is formed by a dry etching process on the passivation layer 170. The conductive etch stop layer 154 is not influenced by an etching gas used during the dry etching process, so that the conductive etch stop layer 154 may prevent the source metal layer 152 from being damaged.

The passivation layer 170 may further include a second hole 172 of the first contact hole CH1 formed in accordance with the first hole 132 of the gate insulation layer 130. The first hole 132 of the gate insulation layer 130 and the second hole 172 of the passivation layer 170 define the first contact hole CH1, and the gate end pattern GP is exposed through the first contact hole CH1. The passivation layer 170 corresponding to the contact part CHT of the TFT QS and the pixel area P is removed in a process for forming the second contact hole CH2, so that the conductive etch stop layer 154 in the contact hole CNT and the pixel area P in the base substrate 110 are exposed.

The transparent electrode patterns PE, GPE and DPE include the pixel electrode PE, the gate pad electrode GPE and the source pad electrode DPE. The transparent electrode patterns PE, GPE and DPE include an optically transparent and electrically conductive layer. The transparent conductive layer includes, for example, indium tin oxide (ITO). Alternatively, the transparent conductive layer may include indium zinc oxide (IZO), which is the same material as the conductive etch stop layer 154.

The pixel electrode PE is electrically connected to the contact portion CNT of the TFT QS. The passivation layer 170 formed on the contact portion CNT is removed to expose the conductive etch stop layer 154. The conductive etch stop layer 154 of the contact portion CNT makes contact with the pixel electrode PE to be electrically connected to the pixel electrode PE. For example, the pixel electrode PE is extended from the contact portion CNT to a side surface of the contact portion CNT. The pixel electrode is electrically connected to a side surface of the contact portion CNT, and is extended to the pixel area P to make contact with the base substrate 110.

The pixel electrode PE formed on the storage electrode STE, the storage electrode STE and the gate insulation layer 130 interposed between the pixel electrode PE and the storage electrode STE define a storage capacitor Cst.

The gate pad electrode GPE is formed in the first contact hole CH1. The gate pad electrode GPE makes contact with an end portion of the second metal layer 124 of the gate end pattern GP, and the gate pad electrode GPE makes contact with a surface of the first metal layer 122 of the gate end pattern GP. Although the gate pad electrode GPE makes contact with an end portion of the second metal layer 124 of the gate end pattern GP, the gate pad electrode GPE makes contact with a surface of the first metal layer 122 so that the gate pad electrode GPE may be electrically connected to the gate end pattern GP.

The source pad electrode DPE is formed in the second contact hole CH2. The source pad electrode DPE makes contact with a surface of the conductive etch stop layer 154 of the source end pattern DP. The conductive etch stop layer 154 prevents the source metal layer 152 of the source end pattern DP from being damaged. Thus, the source end pattern DP is fully contacted with the source pad electrode DPE to be electrically connected to each other.

The source patterns SE, DE, CNT and DP have a structure that the source metal layer 152 and the conductive etch stop layer 154 are sequentially formed, so that the source patterns SE, DE, CNT and DP may prevent the source metal layer 152 of the source end pattern DP from being damaged. Therefore, the source pad electrode DPE makes fully contact with a surface of the conductive etch stop layer 154 of the source end pattern DP, so that reliability of a connection between the source end pattern DP and the source pad electrode DPE may be increased.

Furthermore, the conductive etch stop layer 154 of the contact portion CNT prevents the source metal layer 152 of the contact portion CNT from being damaged, so that reliability of a connection between the contact portion CNT and the pixel electrode PE may be enhanced. For example, in three-mask process using a lift-off of the photoresist film, when a contact portion is formed from a single metal layer, a portion of the conventional contact portion adjacent to a pixel area may be collapsed by removing the passivation layer formed on the conventional contact portion. However, according to the present invention, the conductive etch stop layer 154 prevent the source metal layer 152 according to the contact portion CNT from being damaged, so that reliability of a connection between the TFT QS and the pixel electrode PE may be enhanced.

In FIGS. 1 and 2, the conductive etch stop layer 154 formed on the source metal layer 152 is described. Alternatively, a conductive etch stop layer (not shown) may be formed on the gate metal layers 122 and 124 of the gate end pattern GP so that reliability of a connection between the TFT QS and the pixel electrode PE. The conductive etch stop layer formed on the gate metal layers 122 and 124 may be formed from the IZO metal layer that is same as the conductive etch stop layer 154.

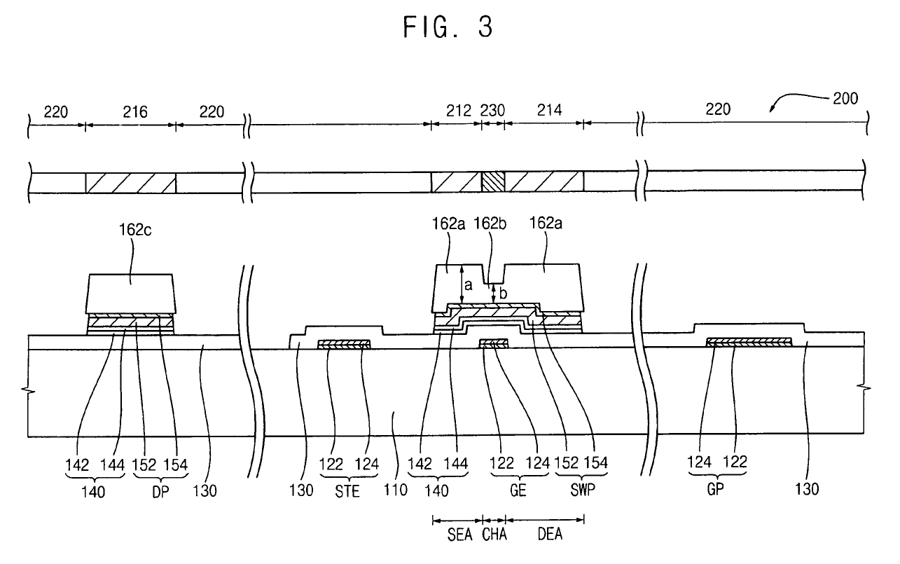

FIGS. 3 to 8 are cross-sectional views illustrating a method of manufacturing the display substrate in FIG. 2.

Referring to FIG. 3, a gate electrode GE, a gate end pattern GP and a storage electrode STE are formed on a base substrate 110 by using a first mask (not shown). A source end pattern DP and a switching pattern SWP are formed on the base substrate 110 by using a second mask 200.

Particularly, gate metal layers 122 and 124 are formed on the base substrate 110. The gate metal layers 122 and 124 include a first metal layer 122 and a second metal layer 124 that are sequentially formed on the base substrate 110. The gate metal layers 122 and 124 are patterned by the first mask to form the gate patterns GE, GP and STE that include the gate electrode GE, the gate end pattern GP and the storage electrode STE, respectively. Gate insulating layer 130 is formed on the base substrate to cover the gate line and the storage electrode. Gate insulating layer 130 may be patterned by a photolithography process and an etching process.

Then, a semiconductor layer 142, an ohmic contact layer 144, a source metal layer 152 and a conductive etch stop layer 154 are sequentially formed on gate insulation layer 130 on the base substrate 110 having the gate patterns GE, GP and STE. A first photoresist film (not shown) is formed on the base substrate 110 having the conductive etch stop layer 154, and first photoresist patterns 162a, 162b and 162c are formed by patterning the first photoresist film using the second mask 200.

The switching pattern SWP and the source end pattern DP are formed by using the first photoresist patterns 162a, 162b and 162c as a mask. The switching pattern SWP is formed in a source area SEA, a drain area DEA spaced apart from the source area SEA by a predetermined interval, and a channel area CHA located between the source area SEA and the drain area DEA.

The source metal layer 152 and the conductive etch stop layer 154 may be patterned using the same etching solution. An etching ratio of the source metal layer 152 is substantially equal to that of the conductive etch stop layer 154. The source metal layer 152 includes, for example, molybdenum (Mo). The conductive etch stop layer 154 includes, for example, indium zinc oxide (IZO). The first photoresist film may include a positive photoresist material that an exposed area is removed by a developing solution. Alternatively, the first photoresist film may include a negative photoresist material.

The second mask 200 includes light blocking portions 212, 214 and 216, a light transmitting portion 220 and a semi-light transmitting portion 230. The second mask 200 may include a slit mask having slits formed in the semi-light transmitting portion 230. Alternatively, the second mask 200 may include a half-tone mask having the semi-light transmitting portion 230 of a half-tone.

The first photoresist patterns 162a, 162b and 162c are formed to have a first thickness a, which is formed on the switching pattern SWP in accordance with the source area SEA and the drain area DEA. The first photoresist patterns 162a, 162b and 162c are formed to have the first thickness a, which is formed on the source end pattern DP. The first photoresist patterns 162a, 162b and 162c are formed to have a second thickness b, which is formed on the switching pattern SWP of the channel area CHA. The second thickness b is thinner than the first thickness a.

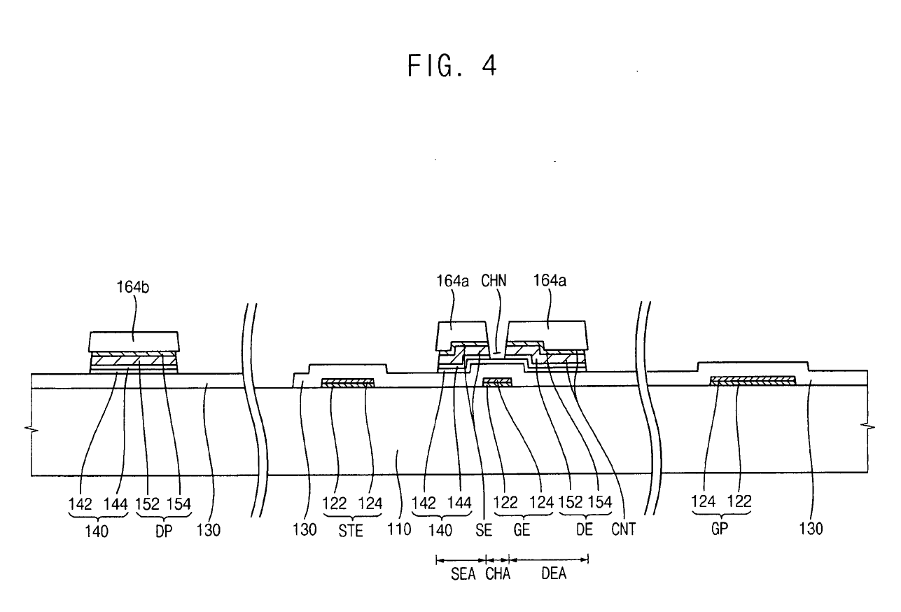

Referring to FIGS. 3 and 4, first remaining patterns 164a and 164b are formed through an etch-back process that removes the first photoresist patterns 162a, 162b and 162c by a predetermined thickness. A source electrode SE, a drain electrode DE, a contact portion CNT and a channel portion CHN are formed using the first remaining patterns 164a and 164b.

For example, the first remaining patterns 164a and 164b are formed on the switching pattern SWP of the source and drain areas SEA and DEA and the source end pattern DP. The switching pattern SWP of the channel area CHA is etched by the first drain patterns 164a and 164b as a mask. Accordingly, a source electrode SE is formed in the source area SEA, and a drain electrode and a contact portion CNT are formed in the drain area DEA. The source electrode SE is spaced apart from the drain electrode DE by an interval in accordance with the channel area CHA.

Then, the ohmic contact layer 144 formed in the channel area CHA is removed using the first remaining patterns 164a and 164b, the source electrode SE and the drain electrode DE as a mask. As a result, a channel portion CHN is formed, to thereby expose the semiconductor layer 142 of the channel area CHA.

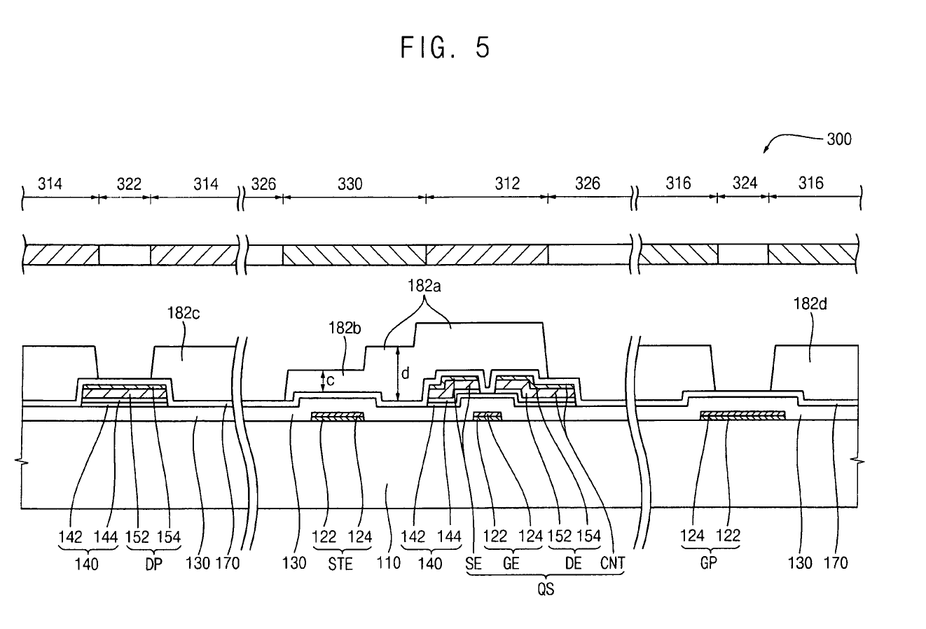

Referring to FIG. 5, a passivation layer 170 is formed on an entire surface of the base substrate 110 having the channel portion CHN and the source end pattern DP. A second photoresist film (not shown) is formed on the base substrate 110 having the passivation layer 170. The second photoresist layer is patterned by a third mask 300 to form second photoresist patterns 182a, 182b, 182c and 182d. The second photoresist film may include a positive photoresist material, and thus an exposed area is removed by a developing solution. Alternatively, the second photoresist film may include a negative photoresist material.

The third mask 300 includes light protecting portions 312, 314 and 316, light transmitting portions 322 and 324, and a semi-light transmitting portion 330. The third mask 300 may include a slit mask or a half-tone mask. The slit mask has a slit formed in the semi-light transmitting portion 330. The half-tone mask is a mask wherein fine holes are formed in the semi-light transmitting portion 330. A light amount passing the semi-light transmitting portion 330 of the third mask 300 is relatively smaller than a light amount passing the light transmitting portions 322 and 324 of the third mask 300, and is relatively greater than a light amount passing the light protecting portions 312, 314 and 316 of the third mask 300. Therefore, a remaining amount of the second photoresist film 180 in accordance with the semi-light transmitting portion 330 of the third mask 300 is relatively smaller than that of the second photoresist film in accordance with the light-protection portions 312, 314 and 316 of the third mask 300. Moreover, the second photoresist film is removed by a developing solution, which corresponds to the light transmitting portions 322 and 324 of the third mask 300.

The second photoresist patterns 182a, 182b, 182c and 182d are formed on the storage electrode STE, the source electrode SE and the drain electrode DR, and expose the passivation layer 170 formed in the gate end pattern GP, the source end pattern DP and the contact portion CNT. The second photoresist patterns 182a, 182b, 182c and 182d formed on the storage electrode STE are formed to have a third thickness c. The second photoresist patterns 182a, 182b, 182c and 182d formed on the source electrode SE and the drain electrode DE are formed to have a fourth thickness d. The fourth thickness d is thicker than the third thickness c.

Alternatively, the second photoresist patterns 182a, 182b, 182c and 182d may include a photo pattern (not shown) formed on the contact portion CNT. The photo pattern may be formed to have the third thickness c. The photo pattern may prevent the contact portion CNT from collapsing that is damaged by an etching gas while performing an etching process on the passivation layer 170.

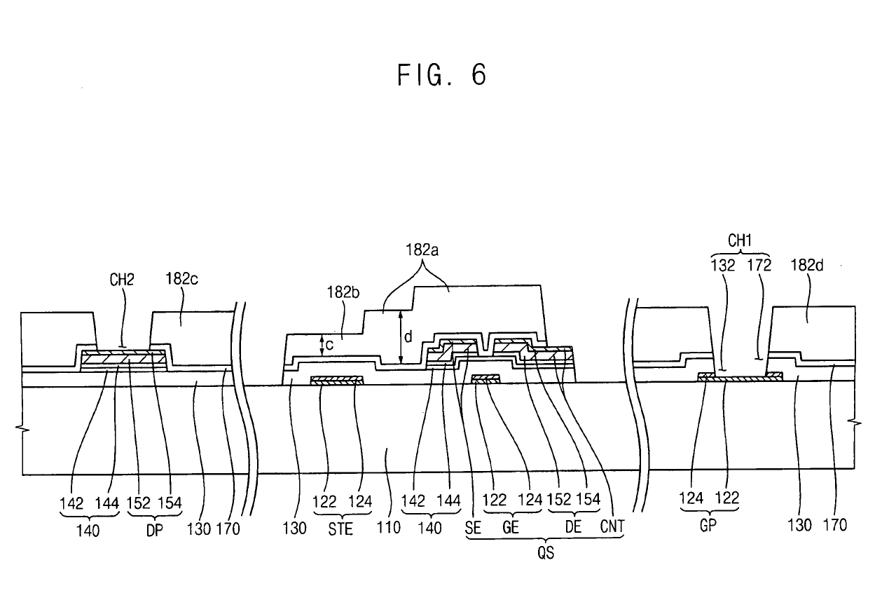

Referring to FIGS. 5 and 6, the passivation layer and gate insulation layer 130 are removed using the second photoresist patterns 182a, 182b, 182c and 182d as a mask. The removal process is performed through a dry etching process using an etching gas, which removes the passivation layer 170 and the gate insulation layer 130. The etching gas may include a sulfur hexafluoride (SF6) gas as a base gas.

The passivation layer 170 formed on the gate end pattern GP and the gate insulation layer 130 are removed to form a first contact hole CH1 that includes a first hole 132 and a second hole 172. The second metal layer 124 of the gate end pattern GP is exposed through the first contact hole CH1. The second metal layer 124 is partially removed by the etching gas, so that the first metal layer 122 may be exposed.

The passivation layer 170 is formed on the source end pattern DP, thereby forming the second contact hole CH2. The conductive etch stop layer 154 of the source end pattern DP is exposed through the second contact hole CH2. Thus, the conductive etch stop layer 154 of the source end pattern DP is not damaged, and the source metal layer 152 of the source end pattern DP may be prevented from being damaged.

When the passivation layer 170 of the contact portion CNT is removed, the conductive etch stop layer 154 of the contact portion CNT is exposed. The conductive etch stop layer 154 of the contact portion CNT may prevent the source metal layer 152 of the contact portion CNT from being damaged. The source metal layer 152 of the contact portion CNT may be protected by the conductive etch stop layer 154 except forming an additional photo pattern on the contact portion CNT, so that the contact portion CNT may be prevented from being collapsed. Here, the passivation layer 170 and the gate insulation layer 130 are removed to expose the base substrate 110, which are formed in the contact portion CNT and a pixel area adjacent the storage electrode STE.

The passivation layer 170 is removed in order to expose the source end pattern DP and the contact portion CNT, whereas the passivation layer 170 and the gate insulation layer 130 are removed in order to expose the gate end pattern GP and the pixel area while performing a process substantially the same as the removal process of the passivation layer 170. Therefore, the source end portion DP and the contact portion CNT may be damaged. However, in accordance with the present invention, the conductive etch stop layer 154 is formed on the source metal layer 152, and thus the source metal layer 152 may be prevented from being damaged.

In a dry etching process of the passivation layer 170, the gate end pattern GP may be less damaged than that of the source end pattern DP. However, the conductive etch stop layer is formed on the gate metal layers 122 and 124, so that the gate metal layer may be prevented from being damaged.

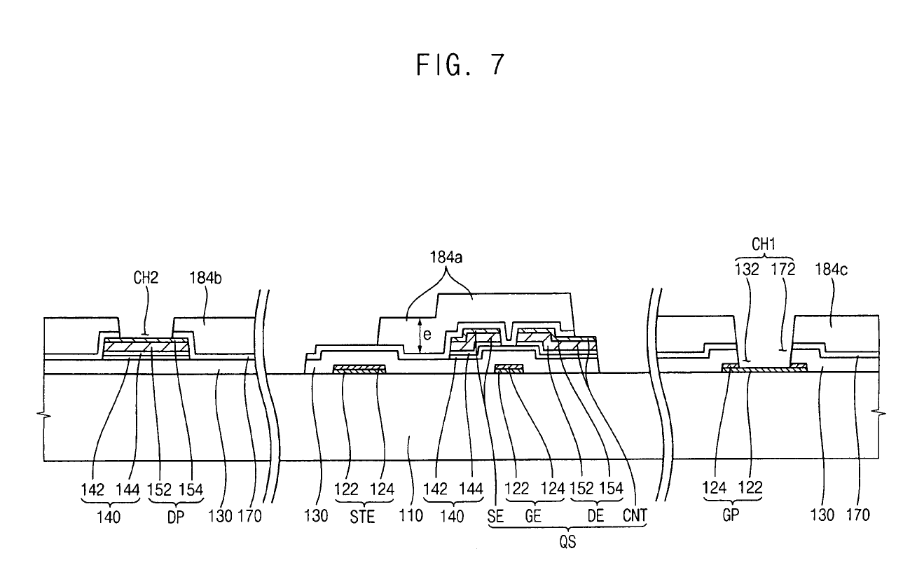

Referring to FIGS. 6 and 7, the second photoresist patterns 182a, 182b, 182c and 182d are etched to form second remaining patterns 184a, 184b and 184c.

The second remaining patterns 184a, 184b and 184c expose the passivation layer 170 formed on the storage electrode STE. For example, the second remaining patterns 184a, 184b and 184c may have a fifth thickness e by removing the second photoresist patterns 182a, 182b, 182c and 182d by the third thickness c. The fifth thickness c may be different from the third thickness c and the fourth thickness d.

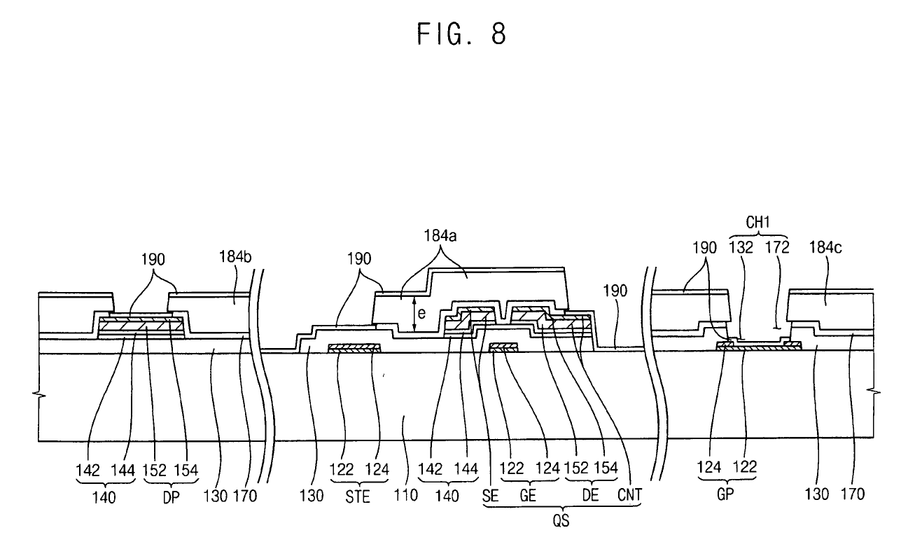

Referring to FIG. 8, an under-cut is formed between the second remaining patterns 184a, 184b and 184c formed on the contact portion CNT and the source end pattern DP, and the passivation layer 170 uses the second remaining patterns 184a, 184b and 184c as a mask. The under-cut may have a structure that the second remaining patterns 184a, 184b and 184c are relatively extruded than the passivation layer 170. In forming the under-cut, the etching gas may include a fluorocarbon (CF4) gas as a base gas.

The under-cut is also formed on the second remaining patterns 184a, 184b and 184c of the gate end pattern GP, the passivation layer 170 and the gate insulation layer 130. In forming the under-cut, the passivation layer 170 formed on the storage electrode STE is removed, so that the gate insulation layer 130 on the storage electrode STE is exposed.

The source end pattern DP and the source metal layer 152 of the contact portion CNT may be damaged by the etching gas used in a process forming the under-cut. However, in accordance with the present invention, the conductive etch stop layer 154 is formed on the source metal layer 152, so that damage to the source metal layer 152 may be prevented. Moreover, the indium zinc oxide (IZO) layer may prevent from damaging the gate metal layers 122 and 124 when the indium zinc oxide (IZO) layer is formed on the gate metal layers 122 and 124 of the gate end pattern GP.

Referring to FIGS. 2 and 8, a transparent conductive layer 190 is formed on the base substrate 110 having the second remaining patterns 184a, 184b and 184c. The transparent conductive layer 190 may be patterned by removing the second remaining patterns 184a, 184b and 184c except an additional mask. The patterned transparent conductive layer 190 is patterned to form a pixel electrode PE, a gate pad electrode GPE and a source pad electrode DPE.

The pixel electrode PE is formed in the pixel area, and is connected with the conductive etch stop layer 154 according to the contact portion CNT. The pixel electrode PE is extended from the contact portion CNT to the pixel area to be connected with the base substrate 110 of the pixel area. The pixel electrode PE is formed on the gate insulation layer 130 of the storage electrode STE to define a storage capacitor Cst.

The gate pad electrode GPE is formed in the first contact hole CH1 in accordance with the gate end pattern GP. The gate pad electrode GPE makes contact with a surface of the first metal layer 122 exposed through the first contact hole CH1, and is contacted with the second metal layer 124 in a peripheral area of the second metal layer 124. Therefore, the gate end pattern GP is electrically connected to the gate pad electrode GPE.

The source pad electrode DPE is formed in the second contact hole CH2 of the source end pattern DP. The source pad electrode DPE makes contact with the conductive etch stop layer 154 that is exposed through the second contact hole CH2. Therefore, the source pad electrode DPE makes full contact with the source end pattern DP to be electrically connected to the source end pattern DP.

According to the display substrate and the method of manufacturing the display substrate, the conductive etch stop layer of the source pad part prevents the source metal layer of the source pad part from being damaged, and the conductive etch stop layer of the source pad part may be fully connected to the source pad electrode. Therefore, contact reliability of the source pad part and reliability of the manufacturing process may be enhanced.

Moreover, the conductive etch stop layer prevents the source metal layer of the contact portion in the switching element protects from being damaged, and thus reliability of a contact between the contact portion and the pixel electrode may be enhanced.

Although the example embodiments of the present invention have been described, it is understood that the present invention should not be limited to these example embodiments but various changes and modifications can be made by one ordinary skilled in the art within the spirit and scope of the present invention as hereinafter claimed.

What is claimed is:

1. A display substrate comprising:
a gate line formed on a base substrate;
a data line crossing the gate line;
a pixel electrode making contact with the base substrate and being positioned in a pixel area; and
a source pad part formed on an end portion of the data line, the source pad part comprising a source metal layer, a conductive etch stop layer formed on the source metal layer and a source pad electrode formed on the conductive etch stop layer.

2. The display substrate of claim 1, wherein the data line comprises a structure where the source metal layer and the conductive etch stop layer are sequentially formed.

3. The display substrate of claim 2, further comprising a passivation layer formed on the data line.

4. The display substrate of claim 3, wherein the passivation layer comprises a contact hole exposing the conductive etch stop layer of the source pad part.

5. The display substrate of claim 1, wherein the source metal layer comprises a metal layer including molybdenum (Mo).

6. The display substrate of claim 5, wherein the conductive etch stop layer comprises indium zinc oxide (IZO).

7. The display substrate of claim 1, further comprising:
a gate pad part formed in an end portion of the gate line,
wherein the gate pad part comprises a gate metal layer and a gate pad electrode formed on the gate metal layer.

8. The display substrate of claim 7, wherein the gate metal layer comprises a metal layer comprising a metal layer that includes aluminum (Al) and molybdenum (Mo) and is formed on the metal layer.

9. The display substrate of claim 8, wherein the gate pad electrode makes contact with an end portion of a metal layer including the molybdenum (Mo) in a peripheral area of the metal layer, and makes full contact with a surface of a metal layer including the aluminum (Al).

10. The display substrate of claim 1, further comprising:
a switching element comprising a gate electrode electrically connected to the gate line, a source electrode electrically connected to the data line and a drain electrode spaced apart from the source electrode,
wherein the source and drain electrodes have a structure that the source metal layer and the conductive etch stop layer are sequentially formed.

11. The display substrate of claim 10, wherein the pixel electrode makes contact with the conductive etch stop layer in accordance with an end portion of the drain electrode to be electrically connected to the conductive etch stop layer.

12. A method of manufacturing a display substrate, the method comprising:
forming a gate metal layer on a base substrate;
forming a gate line and a storage electrode by patterning the gate metal layer;
forming a gate insulation layer on the base substrate to cover the gate line and the storage electrode;
forming a source metal layer and a conductive etch stop layer on the gate insulation layer;
forming a data line, and a source end pattern on an end portion of the data line, by patterning the source metal layer and the conductive etch stop layer; and
forming a pixel electrode contacting the base substrate of a pixel area, and a source pad electrode contacting the conductive etch stop layer of the source end pattern.

13. The method of claim 12, wherein forming the source end pattern comprises:
forming sequentially a semiconductor layer, an ohmic contact layer, the source metal layer and the conductive etch stop layer on the base substrate including the gate line and the storage electrode; and
forming the data line, the source end pattern, a source electrode electrically connected to the data line and a drain electrode using a first photoresist film formed on the conductive etch stop layer.

14. The method of claim 13, wherein forming the source and drain electrodes comprises:
forming the first photoresist film, the first photoresist film being formed on the data line, the source end pattern, a source area and a drain area to have a first thickness, and on a channel area to have a second thickness;
forming the data line, the source end pattern and a switching pattern using the first photoresist film;
removing the first photoresist film by a predetermined thickness to form a first remaining pattern; and
forming a channel portion, the source electrode and the drain electrode using the first remaining pattern.

15. The method of claim 14, wherein forming the source pad electrode comprises:
forming a passivation layer on the base substrate having the channel portion;
forming a second photoresist pattern exposing the passivation layer formed on an end portion of the drain electrode and the source end pattern, the second photoresist pattern being formed on the storage electrode to have a third thickness and on the source and drain electrodes to have a fourth thickness;
exposing an end portion of the drain electrode and the conductive etch stop layer of the source end pattern using the second photoresist pattern;
removing the second photoresist pattern by a predetermined thickness to form a second remaining pattern; and
patterning a transparent conductive layer using the second remaining pattern to form the pixel electrode and the source pad electrode, the pixel electrode being connected to the conductive etch stop layer of the drain electrode.

16. The method of claim 15, wherein patterning the transparent conductive layer comprises:
removing the passivation layer formed on the storage electrode using the second remaining pattern;
forming the transparent conductive layer on the base substrate having the second remaining pattern; and
lifting off the second remaining pattern to form the pixel electrode and the source pad electrode.

17. The method of claim 16, wherein forming the gate line further comprises forming a gate end pattern on an end portion of the gate line.

18. The method of claim 17, wherein forming the source pad electrode further comprises:
removing the passivation layer and the gate insulation layer formed on the gate end pattern exposed through the second photoresist pattern to expose the gate end pattern; and
patterning the transparent conductive layer using the second remaining pattern to form a gate pad electrode making contact with the gate end pattern.

19. The method of claim 15, wherein the source metal layer comprises a metal layer including molybdenum (Mo).

20. The method of claim 19, wherein the conductive etch stop layer comprises indium zinc oxide (IZO).
